(19) United States
(12) Patent Application Publication
(10) Pub. No.: US 2015/0325716 A1
(43) Pub. Date: Nov. 12, 2015

(54) MANUFACTURE AND STRUCTURE FOR PHOTOVOLTAICS INCLUDING METAL-RICH SILICIDE

(71) Applicant: International Business Machines Corporation, Armonk, NY (US)

(72) Inventors: Brett Caroline Baker-O'Neal, Sleepy Hollow, NY (US); Shu-Yun Chong, Singapore (SG); John Michael Cotte, New Fairfield, CT (US); Ronald Dean Goldblatt, Yorktown Heights, NY (US); Jeffrey Hedrick, Montvale, NJ (US); Qiang Huang, Croton on Hudson, NY (US); Susan Huang, Mount Kisco, NY (US); Laura Louise Kosbar, Mohegan Lake, NY (US); Hwee Meng Lam, Singapore (SG); Christian Lavoie, Pleasantville, NY (US); Xiaoyan Shao, Yorktown Heights, NY (US); Rob Steeman, Singapore (SG)

(21) Appl. No.: 14/662,989

(22) Filed: Mar. 19, 2015

Related U.S. Application Data
(60) Provisional application No. 61/990,665, filed on May 8, 2014.

(51) Int. Cl. H01L 31/0224; H01L 31/0216; H01L 31/18

(52) U.S. Cl. CPC H01L 31/022425; H01L 31/1864; H01L 31/02168; H01L 31/18

(57) ABSTRACT

Photovoltaic devices are formed with electroplated metal grids that are effectively adhered to the devices. Metal-rich silicides, such as nickel silicides, are formed on the devices by annealing. The metal used in the anneal exhibits low stress. Annealing may be conducted in ambient air followed by removal of oxide and excess metal from the metal-rich silicide. Laser patterning of the antireflective coating of the devices can be used to expose the emitter to form front grid contacts. Doping of the emitter in the patterned region can be increased during laser patterning. The ratio of the centerline to centerline pitch per laser width is controlled to ensure sufficient adhesion of subsequently plated busbars.

### CROSS-REFERENCE TO RELATED APPLICATION

This patent application claims the benefit of U.S. Provisional Patent Application Ser. No. 61/990,665 filed on May 8, 2014, and entitled “LOW COST MANUFACTURE AND STRUCTURE FOR PHOTOVOLTAICS.” The disclosure of the aforementioned Provisional Patent Application Ser. No. 61/990,665 is expressly incorporated herein by reference in its entirety for all purposes.

### FIELD

The present disclosure generally relates to structures usable in photovoltaic devices and the fabrication thereof.

### BACKGROUND

The manufacture of silicon photovoltaics is a very cost and performance sensitive industry. Standard silicon PV manufacture includes using screen printed silver paste to form the front grid pattern. The silver paste must be fired at a high (>800° C.) temperature to penetrate through the anti-reflection coating (ARC) and achieve sufficient electrical contact to the emitter. This process is undesirable for several reasons, including the high cost of the silver paste, possible substrate breakage during the screen printing process, the negative impact of high temperature thermal processing on the performance of the PV cells, and the quality of the final metal/silicon contact. Screen printing also limits the minimum width and maximum height of the printed features, which results in a higher level of shading of the surface and increased level of series resistance in the fingers than would otherwise be desirable to maximize cell performance.

A better solution would involve direct plating of a metal grid on the front surface. This has been attempted in the past, such as disclosed in U.S. Pat. No. 4,609,565, but one of the primary limitations of plated front grids is the poor adhesion of the metallization to the silicon substrate which can reduce the performance and reliability of the cells. While some of the basic elements of fabricating a plated grid (such as silicide formation and subsequent metal plating) have previously been divulged, these elements alone are insufficient to provide sufficient and reproducible adhesion.

### SUMMARY

Principles of the invention provide techniques for the fabrication of photovoltaic devices. An exemplary method for fabricating a photovoltaic device includes obtaining a substrate including a base comprising silicon, a doped emitter adjoining the base, an antireflective coating on the doped emitter, the antireflective coating being patterned such that the doped emitter has exposed surface portions, and a low-stress nickel film adjoining one or more of the exposed surface portions of the emitter. The method further includes annealing the substrate to form a metal-rich nickel silicide layer NiₓSi_{y} where x>y from the emitter and the nickel film.

In another aspect, a further exemplary method includes obtaining a substrate including: a base comprising silicon, a doped emitter adjoining the base, a silicon oxide or aluminum oxide dielectric layer on the doped emitter, and an antireflective coating on the dielectric layer, laser patterning the antireflective coating to remove portions of the antireflective coating, thereby forming one or more trenches within the antireflective coating, and causing an increase in doping of selected regions of the emitter concurrently with the step of laser patterning the antireflective coating. The exemplary method further includes forming a low-stress nickel film on the selected regions of the doped emitter, annealing the low-stress nickel film and selected regions of the doped emitter to form metal-rich silicide regions having the composition NiₓSi_{y} where x>y from the low-stress nickel film and the selected regions of the doped emitter, forming a nickel layer on the nickel silicide regions, and electroplating a copper layer on the nickel layer.

An exemplary photovoltaic structure includes a base comprising silicon, a doped emitter adjoining the base, a dielectric layer on the doped emitter, a silicon nitride antireflective coating on the dielectric layer, a patterned metal-rich nickel silicide layer adjoining the doped emitter, and a metal grid electrically connected to the patterned metal-rich nickel silicide layer.

Techniques of the present invention can provide substantial beneficial technical effects. For example, one or more embodiments may provide one or more of the following advantages:
Good and reproducible adhesion between a metal grid and a substrate;
Small minimum feature size with reduced shadowing by the metal grid.

These and other features and advantages of one or more embodiments will become apparent from the following detailed description of illustrative embodiments thereof, which is to be read in connection with the accompanying drawings.

### BRIEF DESCRIPTION OF THE DRAWINGS

FIG. 1 is a schematic illustration of a photovoltaic device including a plated finger and busbar;

FIG. 2 is a graph illustrating the force required to separate a copper strip from a plated copper busbar;

FIG. 3 is a flow chart illustrating exemplary steps for fabricating a photovoltaic device;

FIG. 4 is a chart illustrating data from adhesion peel testing as a function of sheet resistance of a busbar just prior to nickel/copper plating;

FIG. 5 is a chart showing adhesion pull force measurement for FLSE busbars as a function of laser pitch for samples cleaned with selected etchants;

FIG. 6 is a chart showing adhesion pull force measurements for FLSE busbars as a function of laser pitch for samples annealed at selected temperatures;

FIG. 7 is a table showing adhesion data from lithographically patterned wafers comparing cells annealed in nitrogen and air with two different nickel etchants;

FIG. 8 is a table showing a comparison of adhesion performance with selected ferric chloride and HF-based pre-plating cleans prior to nickel/copper plating;

FIG. 9 is a table showing a comparison of adhesion performance with selected pre-plating cleans;

FIG. 10 is a table showing a comparison of adhesion data for cells with nickel flash plated using Watts and nickel sulfamate plating chemistries and various plating times;

FIG. 11 is a chart showing adhesion pull strength as a function of laser pitch for various pre-plating etch and anneal conditions;

FIG. 12 is a chart showing average peel strength for each laser pitch of samples annealed at 300° and 320° C. included in the chart of FIG. 11;

FIG. 13 is a graph showing light IV curves of fully processed and plated photovoltaic cells, and

FIG. 14 shows cross sections of metal-rich silicide and a monosilicide formed on silicon-based substrate.

### DETAILED DESCRIPTION

Good adhesion of a metal grid to the emitter of a photovoltaic (PV) cell is critical for transfer of current from the emitter into the metal contacts as well as for long term reliability. Achieving adequate adhesion of copper grids has proven to be a difficult challenge throughout the PV industry. The present disclosure discloses techniques for improving the adhesion of the metal grid.

Adhesion of two materials to each other is influenced by the materials themselves, the surface topography of the interface, the deposition conditions of the materials, and perhaps most importantly the interface between the materials and any interfacial layers that may be present. In the case of plated copper on laser patterned silicon, it was found that all of these aspects could significantly influence the final metal-silicon adhesion, with the interfacial layers playing the largest role.

Adhesion testing on lithographically patterned substrates indicated that several processing steps could positively influence the adhesion, including removal of the excess plated nickel after the silicide anneal, use of a dilute HF clean prior to metal plating, and incorporation of a thin plated nickel flash layer prior to copper plating. Incorporation of these steps generally resulted in improved copper adhesion, although significant variations were observed.

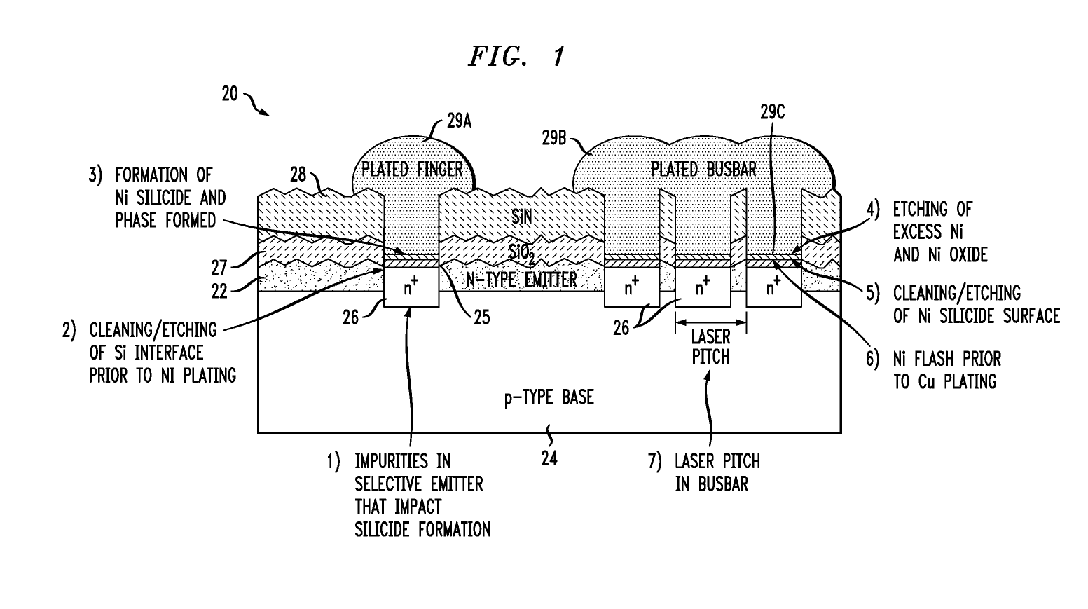

The employment of laser defined patterns, as opposed to lithographically defined features, impacts adhesion. Laser patterned features have less surface area than lithographically patterned features. A small contribution to the reduction in surface area is due to the reduced topography of the laser melted surfaces relative to the initial textured surface. A larger contribution is due to the differences in the patterning techniques. For the laser patterned fingers, the exposed emitter is only about 12 μm wide and the plated copper finger may have a final width of around 30 μm. Lithographically patterned fingers were generally 50-100 μm wide, and the resist restricted any lateral growth of the plated copper. Thus, the laser patterned fingers have much smaller physical and relative surface areas maintaining the adhesive contact between the plated metal and the emitter. For the laser patterned busbars, if non-overlapping laser patterning is used, then the entire busbar surface area is not available for plating (and so cannot contribute to the adhesion) of the metal (for example, copper) as opposed to the full area metal contact for lithographically patterned busbars. Thus, for laser patterned cells good adhesion of the plated metals in the openings to the emitter is important. Silicon nitride films are commonly used for anti-reflection coatings on solar cells based on crystalline silicon. Silicon nitride is essentially transparent to 532 nm laser light employed in one or more exemplary embodiments. Accordingly, ablation of a nitride ARC is not based on direct absorption of energy from the laser, but rather due to the light being absorbed by the silicon below the ARC. Some embodiments, including that shown in FIG. 1, include a silicon oxide (for example, SiO₂) beneath the nitride ARC. In such embodiments, the silicon oxide is optically thin such that it has substantially no impact on ablation. An aluminum oxide layer is formed beneath the nitride ARC in other embodiments. When silicon melts and expands, the nitride is potentially fractured and ejected from the surface. There is also some alteration of the silicon surface. It is not necessarily expected that this would provide a “clean” process, so the surfaces and the bulk of the selective emitters were studied following ablation.

It was determined that there was no single factor that assured good adhesion of the plated metals, but rather a range of factors and processing conditions as depicted in FIG. 1. Factors 1-3 are related to silicide formation, and it is clear that this is one of the most important factors in achieving good adhesion. Factors 4-5 are related to preparation of the surface of the silicide prior to electroplating a metal on it. Factor 6 is related to metal adhesion to the silicide. Factor 7 is related to the impact of laser patterning on the final adhesion of the plated metal in the busbars. Each of these contributing factors are discussed further below. It was determined, however, that with proper substrate, patterning, and processing conditions, good adhesion of electroplated copper to lithographic and laser fine line selective emitter (FLSE) patterns was achievable. Selective emitter cells exhibit relatively low contact resistance due to heavy doping beneath the metal grid.

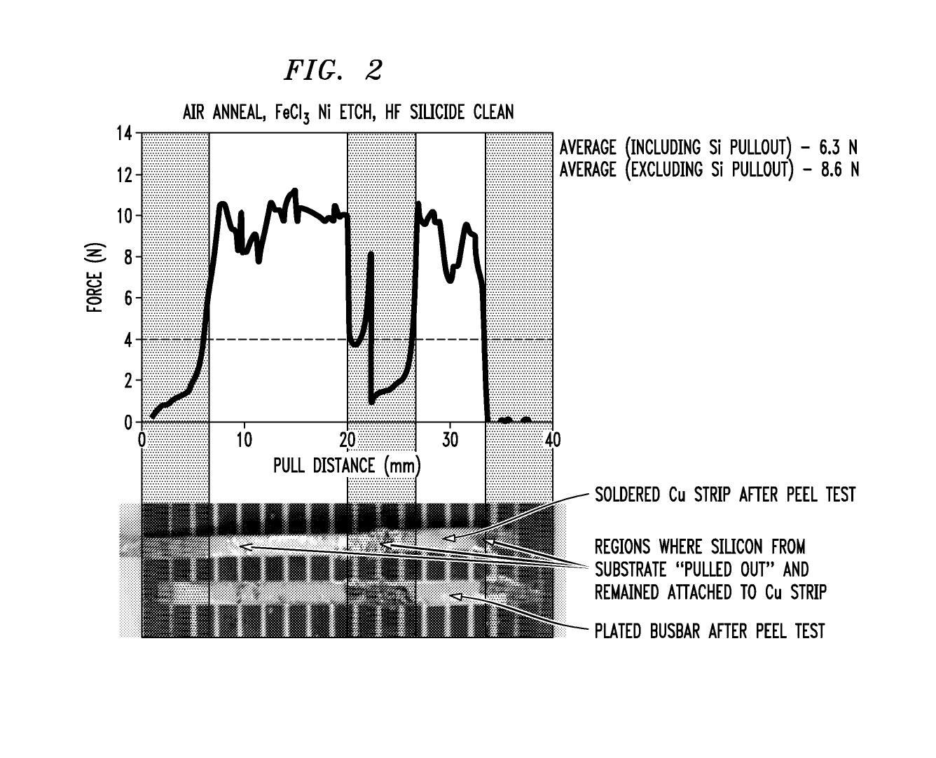

The adhesion tests disclosed herein used the same basic testing procedure. Coupons (4×4 cm²) were cut from standard PV wafers and processed through electroplating copper. Samples with both lithographically patterned grids as well as laser patterned grids were evaluated. After the final plating step, a pre-tinned two mm copper strip was soldered onto the busbar. During soldering, the substrate was on a vacuum chuck heated to 165° C., and the soldering iron was set at 260° C. A standard paste flux was applied to the busbar prior to soldering. The copper strip was approximately five cm longer than the coupon to allow it to be mounted into the peel tester. After soldering, the coupon was mounted onto a glass slide using a fast drying cyanoacrylate resin. Gluing the coupon to the glass slide improved the ease of mounting into the peel testing fixture and reduced silicon breakage during testing. The test coupon was then mounted onto a movable sled on an Instron® Materials Tester, which is capable of measuring and recording the force required to peel the copper strip off the test coupon. The free end of the metal strip was clamped in jaws attached to the measurement head of the tester. The sled is attached to the head of the tester such that as the head moves up, the sled slides back to keep the strip being peeled off at a 90° angle. During the peel test, the measurement head was raised at a constant speed of 50 min/min. As the head moves up, it peels the copper strip off the busbar, and the three required is constantly recorded. The recorded force can vary based on what adhesion failure mechanism occurs. Poor adhesion generally resulted from interfacial failure between the plated copper and the silicide. Samples with good adhesion often experienced cohesive failure within the solder bonding the copper strip to the plated copper or within the silicon substrate itself. When cohesive failure of the substrate occurred, chunks of silicon would be pulled out of the substrate and remain attached to the copper strip. The fractured pieces of silicon were often two to five mm long, and sometimes even longer. Since the measurement head was moving at a constant speed of 50 mm/minute, this type of failure mechanism would cause temporary drops in the measured force until the head had moved up enough to re-engage with a section of the copper strip that was still attached to the substrate. An example of the peel data for a strip with cohesive failure of the silicon substrate is included in FIG. 2. An optical image of the copper strip and associated busbar is included below the peel data to demonstrate how drops in the measured force occurred when pullouts in the silicon substrate occurred. The adhesion values reported for samples are the average of the peel forces for a specific sample or set of samples. All data collected during a given sample pull, from when the strip initially begins to peel off the substrate until it is completely removed from the substrate, is included in the average. In FIG. 2, the average force was calculated both by including all data and by averaging the data in regions not impacted by silicon pullouts. As discussed, silicon pullouts can significantly reduce the reported adhesion value even though they are not indicative of poor adhesion of the copper plated grid. In general, however, samples with plated grid adhesion that is sufficient to lead to cohesive failure of the silicon have average adhesion force measurements that exceed the minimum exemplary specification of 1.9N.

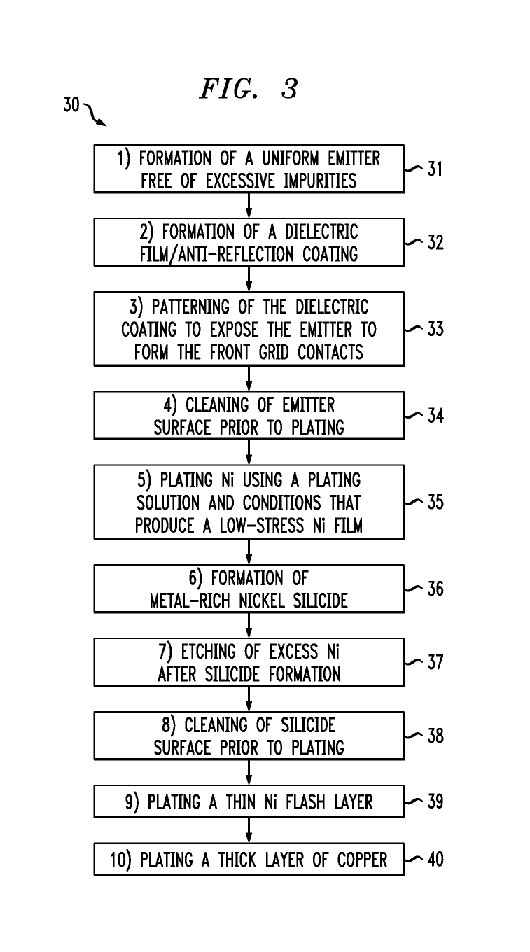

FIG. 3 shows a flow chart of a process 30 used in one or more embodiments for fabricating photovoltaic devices including metal plated front grids. The exemplary device 20 shown in FIG. 1 can be fabricated using the process steps shown in FIG. 3. The initial step 31 of the exemplary process includes forming a continuous emitter with a uniform thickness free of excessive impurities that might prohibit the formation of a good nickel-silicide. An example of such an impurity is nitrogen. The emitter may be formed by a variety of different techniques, including but not limited to POCl₃ diffusion, implantation or epitaxial growth of a doped layer. The thickness of the emitter is typically in the range between 0.2 and 1 micrometer. In step 32, an anti-reflective, dielectric coating (ARC) is formed over the emitter. The dielectric coating is patterned in step 33 to expose portions of the emitter that later form the front grid contacts. The surfaces of the exposed emitter portions are cleaned in step 34 followed by plating thereof in step 35. In the exemplary process, a low-stress nickel film is formed in step 35. In step 36, a metal-rich, nickel silicide layer is formed. Excess nickel is etched after silicide formation in step 37. The silicide surface is cleaned in step 38. In step 39, a thin nickel (Ni) flash layer is plated on the silicide layer. A thick metal layer such as a copper layer is plated on the flash layer in step 40. Further details relating to the steps shown in FIG. 3 are described below.

Formation of nickel silicide (step 36 in FIG. 3) is an important step in the fabrication of plated copper front grids for PV cells. The silicide decreases the contact resistance of the metal to the emitter, acts as a barrier layer for copper diffusion into the cell, and improves the adhesion. When a silicide is not present, the adhesion of the plated copper, even with the use of a nickel flash layer, is very poor. One of the simplest measures of silicide formation is the sheet resistance of the busbar. In general, nickel silicides have sheet resistances between about 5-25 ohm/square, with monosilicides at the low end of that range, and metal-rich silicides in the middle to upper end of the range. In general, for sheet resistance measurements above 25 ohm/square, there was no, or only patchy/discontinuous silicide formed. As can be seen from the data in FIG. 4, there is a dramatic difference in the measured peel strength of copper plated on busbars which had sheet resistances indicative of silicide formation, and those that did not. All of the samples included in this plot were lithographically patterned, so the busbars had not been melted by a laser, retained the original surface texture, and the initial sheet resistance of the emitter was equivalent to that of the background emitter (˜60-70 ohm/sq.). For samples with silicide, the peel strength was generally between 4-7N, while for those with no apparent silicide, the peel strengths were below 1N. A continuous silicide layer appears to be a critical factor in achieving good adhesion of plated metals to standard PV emitters.

As discussed above, a range of factors and processing conditions affect adhesion of plated metals in photovoltaic devices. The level of impurities in the selective emitter, such as nitrogen impurities, is one of the factors. Laser patterning to ablate the ARC and selectively dope additional phosphorous into the emitter to form n+ regions (regions 26 in FIG. 1) can also introduce high levels of nitrogen (N) into the emitter. This was particularly true for nitride only ARC films. The levels of dissolved nitrogen in FLSE formed with nitride only ARC were about an order of magnitude higher than those for oxide/nitride hi-layer ARCs as shown in FIG. 1. High levels of nitrogen dissolved into the silicon seem to inhibit silicide formation, as discussed further below. There was very little silicide observed in nitride only selective emitters at either the normal anneal conditions around 300° C., or even at 400° C. For selective emitters formed on cells with oxide/nitride ARC, which had less dissolved nitrogen, thin uniform layers of metal-rich silicide formed at 300° C. and thicker mono-silicide was observed when annealed at 400° C. The lack of a uniform silicide layer for selective emitters with nitride only ARC produced cells with poor copper adhesion if laser patterning was employed.

By growing a thin (for example, approximately 25 nm) layer of silicon dioxide or aluminum oxide on the emitter surface prior to silicon nitride deposition and subsequent laser patterning, high levels of nitrogen within the emitter can be avoided. The thin oxide layer at the surface decreases the levels of nitrogen in the emitter by as much as an order of magnitude and allows silicide formation in the patterned region. The dielectric layers (elements 27, 28 in FIG. 1) can be formed by any suitable deposition technique including, for example, chemical vapor deposition (CVD), plasma enhanced chemical vapor deposition (PECVD), physical vapor deposition (PVD), sputtering, or atomic layer deposition. Silicide formation is a key to achieving good adhesion between a metal grid and the substrate.

In order for a uniform silicide to form, as described hereafter, there should be intimate contact between the deposited metal (such as nickel) and the emitter surface. If an organic patterning technique (for example lithography or ink jet printing) is employed in step 33 (FIG. 4), processes that completely remove the organics, such as oxygen plasma, reactive ion etch (RIE) processing, or UV ozone steps should be included. In embodiments wherein laser patterning is employed, residual dielectric material may remain. Wet or dry etching steps may be performed to remove such residual dielectric material. In embodiments where multiple dielectric layers are employed, such as the silicon dioxide and silicon nitride layers 27, 28 shown in FIG. 1, the etch should be targeted on the dielectric layer in contact with the emitter, such as a buffered oxide etchant (BOE) to preferentially remove residual oxide.

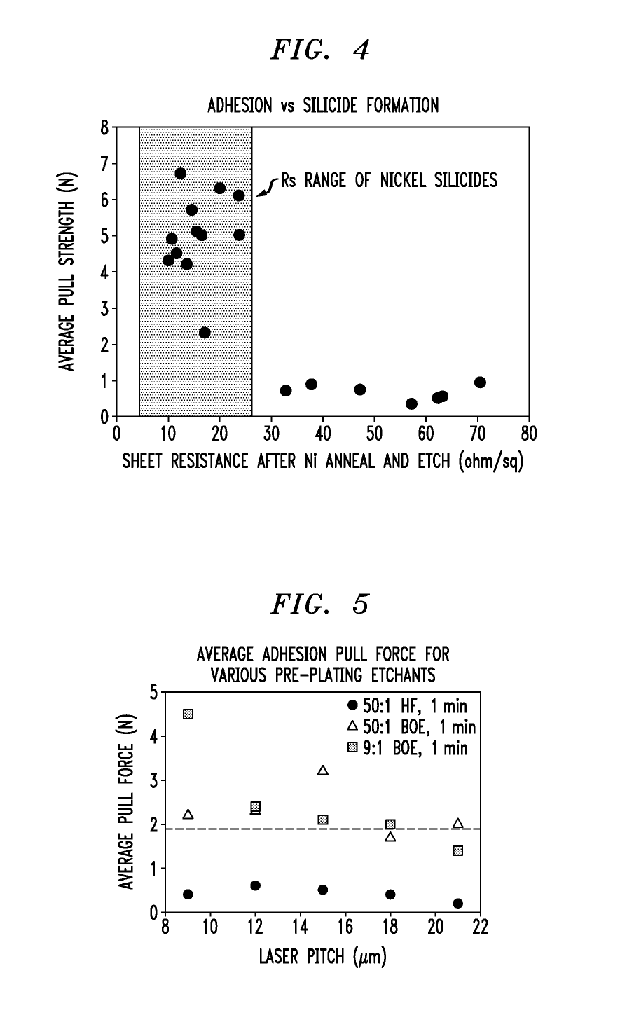

The choice of etchants is a relevant factor in removing residues of the dielectrics remaining following laser patterning of ELSE through an ARC. It was found that hydrogen fluoride (HF) based etchant used to clean the emitter surface prior to the initial nickel plating could significantly impact both the uniformity of the plating and subsequent silicide formation, at least for embodiments including an oxide/nitride dielectric stack where the levels of dissolved nitrogen are low enough for silicides to form. Adhesion studies on cells fabricated with oxide/nitride ARC and FLSE patterns confirmed the impact of adequate removal of residual dielectrics on the adhesion of a plated copper grid pattern. Samples were fabricated with varying pitch—from overlapping to about twice (2×) the laser width—on oxide/nitride substrates. The cells were etched for one minute immediately prior to nickel plating in either 50:1 HF (˜1% HF), 50:1 BOE, or 9:1 BOE. The plated nickel was annealed for five (5) minutes at 300° C., the excess nickel was etched off, and the cells received a standard Ni/Cu plate. Significant variations in adhesion were observed between samples that received a dilute HF clean prior to plating, which had poor adhesion, compared with those that received a BOE clean, which had acceptable adhesion. The individual sample results for busbars with laser pitches between 9 and 21 μm are included in FIG. 5. The average peel forces over this range of laser pitches for the various HF etchants were as follows: 50:1 HF-0.42 N; 50:1 BOE-2.28 N, 9:1 BOE-2.48 N.

The adhesion values obtained from the sample results are lower than observed previously for lithographically patterned busbars. The laser patterned busbars are slightly narrower (˜1.8 mm) than lithographically patterned busbars (˜2 mm). Also, for laser pitches greater than 12 m, there are stripes of unpatterned dielectric within the busbar. Even though the copper plates together create a continuous plated surface on which to solder the copper strip for peel testing, the regions of unpatterned dielectric reduce the plated surface area at the emitter interface which provides adhesion within the busbar region. For these reasons alone, it is expected that the adhesion values measured for FLSE busbars would be 10-50% lower than those measured fir the lithographically patterned busbars. Additional impacts of the laser patterning process, such as the loss of surface topography or the incorporation of contaminants, could also influence the measured adhesion values. For the samples pre-cleaned with 50:1 HF, the adhesion loss was generally between the plated copper and the silicide, such that the plated copper remained on the soldered copper strip. The samples pre-cleaned in either BOE (buffered oxide etch) generally experienced cohesive failure either of the solder between the copper strip and the plated copper or within the silicon substrate itself. Silicon pullout contributes to the variation in the measured peel forces.

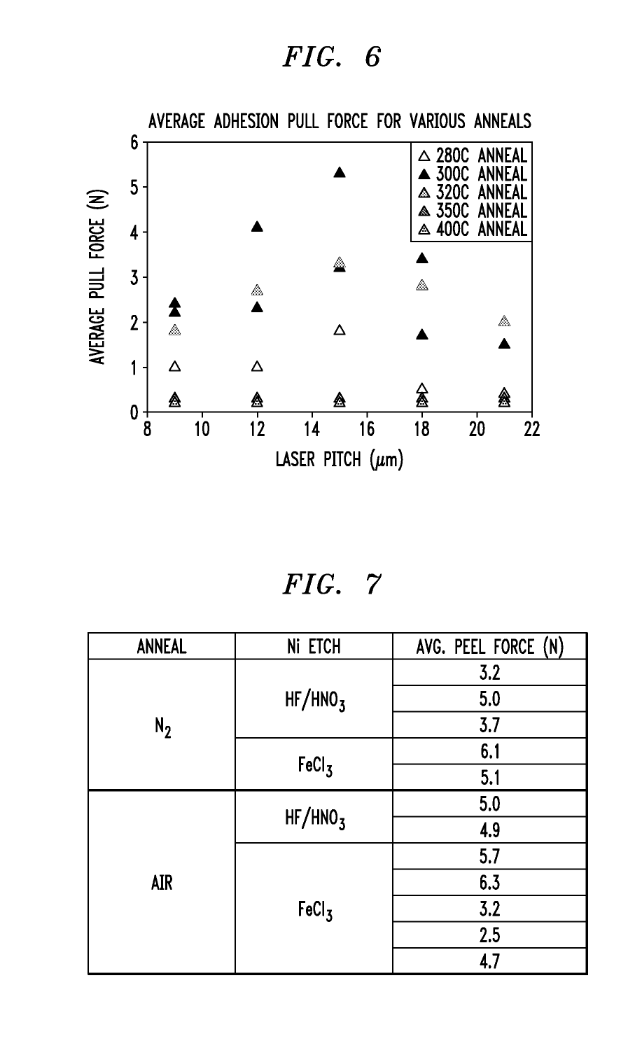

Formation of nickel silicide requires heating of nickel and silicon while they are in intimate contact. The nickel will diffuse into the silicon and, depending on the anneal temperature form one of several phases, including a group of “metal-rich” phases (NiₓSi_{y} where x>y, ˜280-350° C.), a mono silicide (NiSi, ˜350-600° C.), and a disilicide (NiSi2, ˜600° C. and up). The monosilicide has the lowest sheet resistance; however it consumes approximately twice as much silicon as the metal-rich silicides. Emitters on PV cells are generally quite thin, so to avoid shunting, the metal-rich silicides were considered to be advantageous. Metal-rich silicides have another advantage over the monosilicide—they form a very thin and uniform layer, while the mono silicide tends to be much thicker and more nonuniform in texture, including spikes that can penetrate deeper into the silicon and potentially shunt through PV emitters. (See FIG. 14.) In applications where deposition of very thin and controlled layers of nickel are possible, such as metal sputtering or evaporation, it is possible to consume the entire nickel film and form thin layers of the monosilicide. But, to achieve a continuous plated layer of nickel, the final metal layer is too thick to fully consume without shunting the entire emitter. Using lower anneal temperature to form the metal-rich silicides allows a high degree of control of the silicide layer thickness and uniformity. The metal-rich silicide has also proven to be advantageous with respect to metal adhesion. FLSE busbars with various laser pitches were annealed for five minutes at temperatures from 280° C. to 400° C. with varying adhesion performance (FIG. 6). The 280° C. anneal will form a very thin and potentially discontinuous metal-rich silicide. These samples exhibited marginal adhesion. The 300-320° C. anneals form uniform layers of the metal-rich silicides. They produced generally good adhesion, especially for laser pitches between 12-18 μm. The 350-400° C. anneals will form a monosilicide. The monosilicide samples had the worst adhesion, and were all below 1 N. Many of the copper strips peeled off of the samples while they were being mounted in the Instron® test machine. Thus, forming the metal-rich phase of the silicide can be critical for achieving good adhesion of electroplated copper following laser patterning.

Another important aspect of the silicide anneal performed in one or more embodiments is the use of ambient gas. Most silicide anneals are performed in an inert atmosphere to avoid oxidation of the metal prior to silicide formation. For electroplated PV applications, however, only a small portion of the metal was converted to a silicide and oxidation would only occur at the upper surface of the nickel Annealing in air would be far more cost effective in a manufacturing environment than in an inert atmosphere. Therefore, the impact the annealing ambient on silicide formation was investigated. It was found that the silicide formation was in fact comparable, however the oxidized nickel was difficult to etch in the traditional dilute (35%) nitric acid. Nitric acid effectively dissolves nickel metal, but it does not readily dissolve nickel oxide. Therefore, a new etchant system would be required to establish a manufacturable process using an air ambient for the silicide anneal.

Two different approaches were investigated to effectively etch the excess nickel and the surface nickel oxide after the silicide anneal (step 37 of FIG. 3). In the first, a preliminary one minute etch in dilute (1%) Hf was used to dissolve the nickel oxide, followed by the established three to five minute etch in 35% HNO₃ to remove the remaining metallic nickel. The second approach was to use a single, commercially available etchant based on ferric chloride (FeCl₃) and hydrochloric acid (HCl) which dissolves both nickel metal and oxide. This etchant was a 10:1 dilution of TRANSENE™ Nickel Etchant Type 1. Sheet resistance measurements from cells annealed in air and then etched in each of the etchant systems did not appear to adversely impact the silicide during the initial nickel etch.

While the dual HF/HNO₃ etchant system was fairly effective at removing both the nickel and oxide, it had several downsides. Two separate etch baths, along with the associated rinse tanks, would require more space in a manufacturing line, and might be more expensive to maintain. In addition, for highly oxidized samples, the initial HF etch did not always remove all of the nickel oxide and these samples had to go through the HF/HNO₃ cycle a second or even a third time. Extending the length of the HF etch did not succeed in removing the nickel oxide in these cases until the samples had been exposed to the nitric acid etch. Sheet resistance (Rs) measurements after each of these etch cycles also revealed that the Rs of the silicide was increasing, indicating that the HF/HNO₃ etchants were slowly etching the silicide. The final Rs values after 2-3 etch cycles exceed the desired twenty (20) ohm/square maximum for the nickel silicide.

The FeCl₃, based etchant produced good sheet resistance values after a single etch and also appeared to produce smaller distributions of measurements than the samples etched in HF/HNO₃. Another advantage of the FeCl₃ etchant was that there seemed to be no impact on the silicide if it is exposed to this etchant for extended periods. The samples that were subjected to a second and third etch demonstrated no increase in sheet resistance. Because this etchant effectively etched both Ni and NiO, there were no cases where a second etch was even required.

The impact of both the air anneal and the FeCl₃ etchant on adhesion were evaluated, and the data is included in the table shown in FIG. 7. No gross differences were observed between any of the cells in this matrix, indicating that the air anneal and the ferric chloride etch do not appear to adversely impact adhesion. Both the air anneal and ferric chloride etch are included in one or more embodiments of the processes disclosed herein.

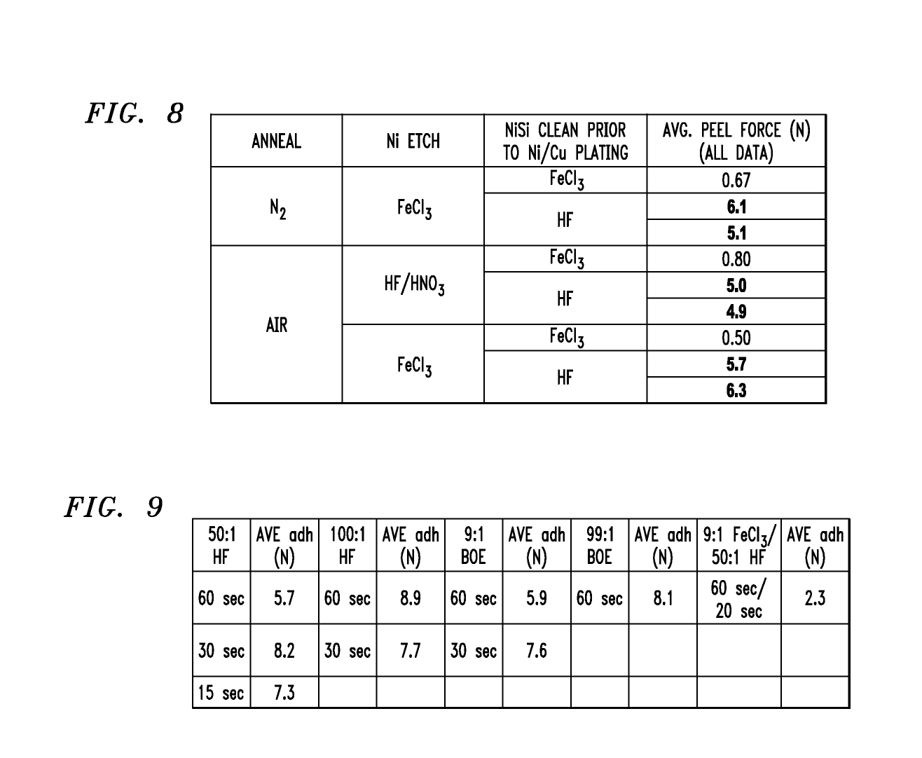

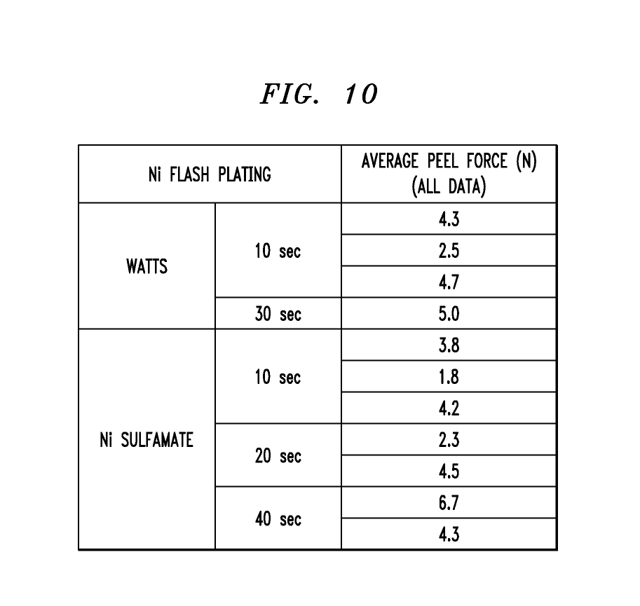

As with the emitter surface before nickel plating, the state of the silicide surface prior to the Ni/Cu plating is very important to achieve good adhesion. The process of record (POR) pre-plating clean was a sixty (60) second etch in 50:1 HF. As part of the development of the air anneal and ferric chloride etchant, the question arose whether the pre-clean was required to remove silicon oxide or nickel oxide. If nickel oxide were the issue, then the ferric chloride etchant might be effective as a pre-clean without etching the nitride and exacerbating ghostplating issues. Adhesion samples were prepared using either a ferric chloride etch or the POR HF etch. These splits were included with the anneal and nickel etch splits, and the data is included in the table shown in FIG. 8. In all of the cases tested, the samples that had a ferric chloride pre-plating clean had very poor adhesion compared to those with an HF clean. This indicates that it is likely that silicon dioxide is more significant at decreasing interfacial adhesion of the plated metal to the silicide than nickel oxide. Any pre-plating clean that uses IV based solutions can etch the ARC and contribute to ghostplating. For embodiments including the oxide/nitride ARC, buffered oxide etchants (BOE) etch oxides much more rapidly than nitrides, and could minimize the increase in ghostplating. A set of samples was prepared to evaluate the impact on adhesion of various etchants and etch times. The data is included in the table shown in FIG. 9. From this study, it appeared that any HF based etchant worked well as a pre-plating clean of the silicide surface—even for etch times as short as fifteen seconds. The cell with the poorest adhesion had a two-step ferric chloride and HF etch. This confirms that ferric chloride is a poor choice to include even as part of a preplating clean process.

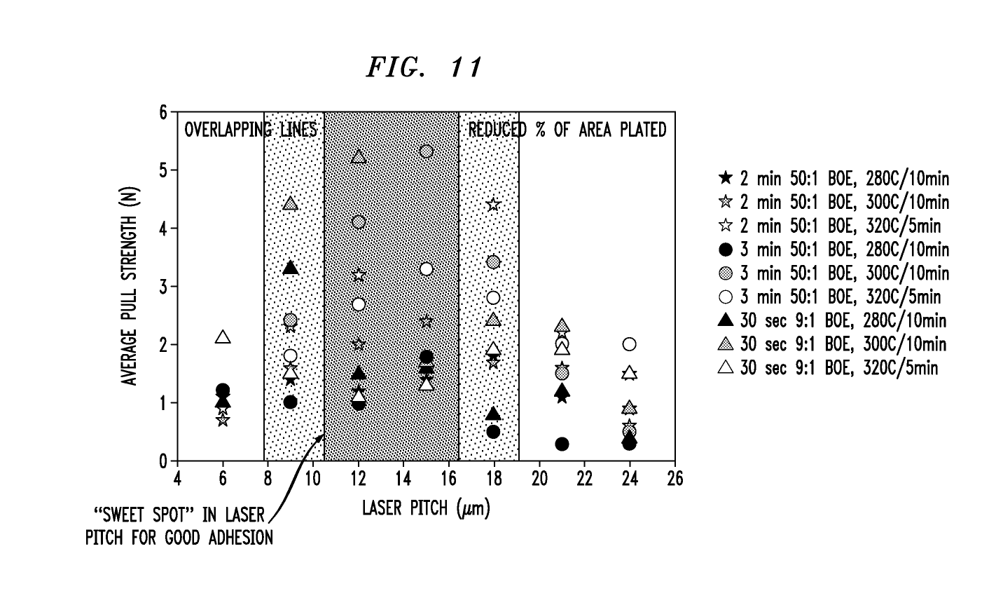

The adhesion of copper plated directly onto nickel silicide is generally poor. The adhesion was greatly improved, however, by plating a thin layer of nickel (referred to as a nickel flash) in step 39 of FIG. 3 prior to plating the copper. Results indicated better adhesion using a Watts nickel plating chemistry compared to the nickel sulfamate plating chemistry used for the initial nickel plating step (step 35 of FIG. 3). It would be more expensive in a manufacturing process to maintain two different nickel plating chemistries, so the impact of the nickel flash chemistry on adhesion was revisited. In addition to comparing the plating chemistries, it was also important to evaluate the impact of plating time, as the prototype plating tools under consideration were expected to have a minimum plating time of 20-30 seconds. Samples were prepared using lithographic patterning and plated with both Watts and sulfamate plating chemistries with varying plating times. The results are included in the table shown in FIG. 10. No significant differences were observed between the adhesion of samples with the Watts plated nickel compared to those plated in a nickel sulfamate bath. No significant differences were observed based on plating time, either. Based on these results, it was determined that the nickel sulfamate plating bath with a forty (40) seconds plating time could become the POR for nickel flash plating in one or more embodiments of the process.

The laser used to create fine line selective emitters in accordance with one or more embodiments produces about a 12 μm wide opening in the nitride layer for a single laser pass. While a single pass is sufficient for opening the fingers, this is not true for the busbars. Busbars are generally about 2 mm wide, and so require multiple parallel laser passes. The center-to-center spacing, or pitch, between subsequent laser passes can be varied from having overlapping lines to having gaps of unpatterned nitride between the lines. FIG. 1 schematically illustrates a plated finger 29A and a plated busbar 29B as well as the laser pitch in the busbar area. From an adhesion viewpoint, it would be expected that overlapping or at least abutting lines would provide the most plated surface area and result in the best adhesion, but from a cost perspective, using a wider pitch would require fewer laser passes and less time/cost. Experiments on the impact of FLSE and pitch indicated that overlapping laser lines led to higher concentrations of dissolved contaminants, such as nitrogen, in the emitter, which was shown to influence silicide formation and could also impact the adhesion. An adhesion study was performed evaluating laser pitches from 6 μm (100% overlap) to 24 μm (1× nitride gap between laser lines). Three different pre-plating etch conditions were used prior to the initial nickel plating—50:1 BOE for two or three minutes, and 9:1 BOE for 30 seconds. Three different anneal conditions, all of which should produce the metal-rich silicide, were used—280° C. for ten (10) minutes, 300° C. for ten (10) minutes, or 320° C. for five minutes. The results of this study are included in FIG. 11.

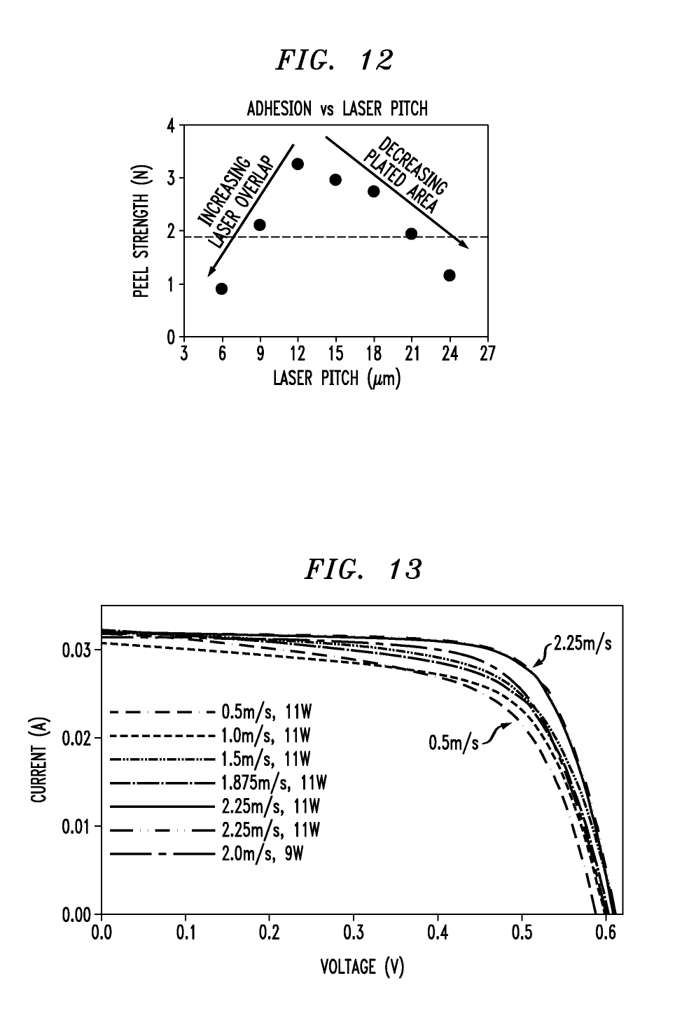

Slight variations in the adhesion strength for the varying process conditions were fairly consistent with previous studies. The adhesion values for the 280° C. anneal were lower than those for the higher temperature anneals. In this study, the time for the 280° and 300° C. anneals was increased to ten (10) minutes, and under these conditions, the samples with a 300° C./10 minute anneal had slightly better adhesion than those with a 320° C./5 minute anneal. No consistent trends emerged between the various etch conditions. From the data in FIG. 11, there appear to be distinct trends in the adhesion data relative to the laser pitch. To make this more apparent, the data for the samples annealed at 300° or 320° C. and all pre-clean conditions were averaged for each pitch and the results plotted in FIG. 12. The highest adhesion values were obtained for laser pitches close to the nominal laser linewidth. In general, the best adhesion was found for the 12 and 15 μm pitches. As the pitch increased, the adhesion decreased. This was expected, as there was less plated metal in contact with the silicide for these samples since the area between the laser lines was still covered with nitride. Since copper plating is isotropic, the plated lines expanded laterally as well as vertically so that they joined into a continuously plated busbar (as shown schematically in FIG. 1) even for the 24 μm pitch, but in this case only half of the area underneath the busbar was in contact with the emitter. From the point of view of adhesion, it appears that the maximum laser pitch should be no more than 15-18 μm for a laser producing a 12 μm opening. In other words, a pitch of between 0.8-1.5 of the width of a single laser pass is expected to produce satisfactory results.

As the pitch decreases below the nominal laser linewidth, the adhesion also decreases. For all of these samples, the plated metal should be in contact with the entire area underneath the busbar, so one would nominally expect them to have similar high levels of adhesion. It is possible that the increased level of contaminants and doping introduced into the overlapped laser patterns, the reduced level of silicide formation, or possibly even damage done to the emitter from multiple laser passes adversely impacts the adhesion. It is clear, however, that to achieve optimal adhesion overlapping laser lines should be avoided and the minimum pitch should be near or above the laser linewidth.

The impact of laser patterning can be observed visually due to removal of the ARC layer(s) and melting of the silicon which eliminates the surface texture in the patterned regions. The impacts below the surface can be determined using scanning capacitance microscopy; for example the depth of the emitter in the laser patterned regions as well as the depth of the background emitter can be so determined. From the SCM images (not shown), it appeared that the emitter depth for the background emitter was about 200 nm in one exemplary embodiment while the selective emitter was as much as 1500 nm thick. The SCM cross section also shows the reduction in topography in the laser patterned region due to melting of the silicon.

The amount of energy deposited in the silicon during laser patterning is largely controlled by the power and speed of the laser beam. In regions such as the busbars, where multiple passes of the laser are used to create wider areas with selective emitters, the pitch of the successive laser passes is also important, as discussed above.

The laser conditions included laser powers from seven to eleven watts and laser speeds from 0.5-4 mls in some embodiments. Standard cells with an 85 nm PECVD nitride ARC were used for the evaluation of laser impacts and cell performance in some embodiments, and polished single crystalline wafers with nitride were used to evaluate the SIMS profiles of the selective emitters. SIMS (secondary ion mass spectrometry) measurements provide information about the concentration of elements vs. depth relative to the surface of the sample. The concentration vs depth profile of the background emitter was consistent with a shallow emitter with a high surface concentration of phosphorous as expected.

The laser patterning of the selective emitters was performed by spinning phosphoric acid onto the cell as a source of phosphorous prior to laser patterning in some embodiments. This allows increasing the doping of selected portions of the n-type emitter during the step of laser patterning (step 33 of FIG. 3). The SIMS curves for the laser patterned features (not shown) indicated that the phosphorous concentration in the emitters was very uniform throughout the thickness of the emitter, which is consistent with melting of the silicon during laser patterning followed by rapid cooling. The FLSE did not have a high surface concentration of phosphorous as observed in the diffused background emitter, but had concentrations consistently around 5×10¹⁹ atoms/cm³. This doping level is sufficient for processes as disclosed herein where metallization involves copper plating as opposed to screen printing. There was essentially no difference in the emitter concentration or depth for features patterned with seven or eleven W of power and the same laser speed, but when the power is kept constant and the speed varied, the feature written with the faster speed (less energy deposited) has a shallower depth, as would be expected.

Scanning capacitance microscopy (SCM) of selective emitters formed using different laser conditions were fairly consistent with the SIMS results. The emitter fabricated using the higher power laser conditions (11 W) appears to be slightly deeper, with an average depth just over 5 μm, while the sample written at 7 W laser power appears to have an average depth around 4.5 μm. Considering the spot size of the SIMS and the small area interrogated by SCM, these measurements indicate a reasonable consistency between the two techniques, and indicate that the impact of laser power on emitter depth is rather small.

The surfaces of the various selective emitters were also evaluated by scanning electron microscope (SEM). Slight differences were observed, with the faster speeds and/or lower powers showing a bit more texture or residue on the surface of the emitter. The emitter formed with the slowest speed laser, and hence with the greatest amount of energy deposited in the silicon, had a large number of what appeared as “black spots” on the surface of the emitter. When cross-sections of these samples were prepared, voids, blisters or inclusions near the surface were apparent along with residues containing high levels of nitrogen and oxygen. Emitters formed using very low speeds appear to have more surface damage which would be less desirable for cell fabrication.

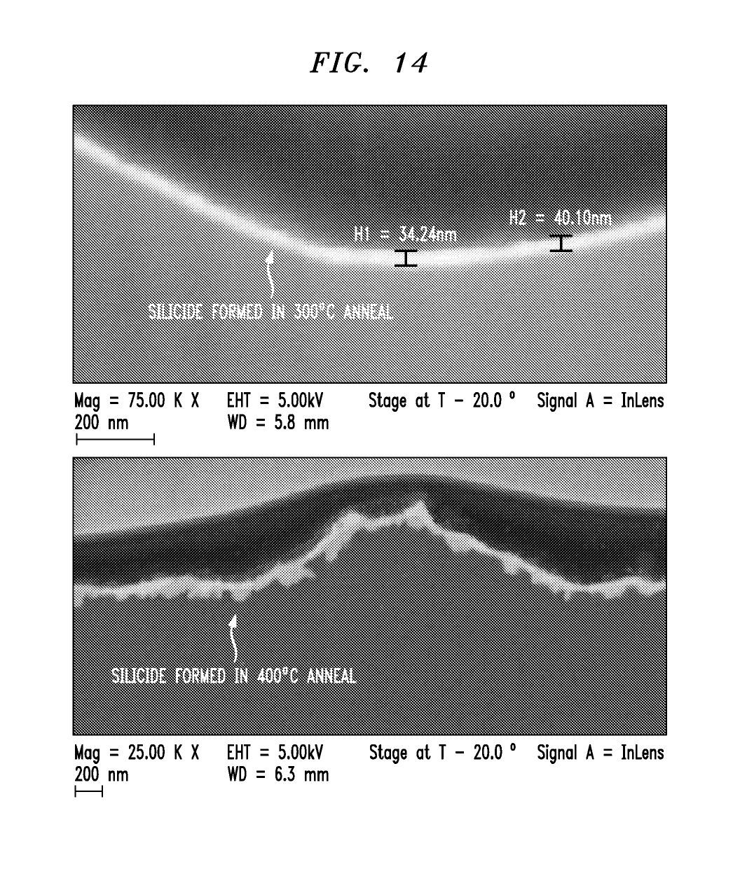

Exemplary cells were fabricated through the full copper plated grid process and their performance measured (FIG. 13). A 300° C. anneal of the nickel was used to avoid shunting in ghostplated regions. As can be seen from the IV curves, the cell with the slowest writing speed had the worst performance—which may be related to the surface damage that was observed by SEM. The cells that had the best performance were those with the highest power and highest writing speed (2.25 Mk). Thus, an exemplary set of “standard laser conditions” was defined as 11 W power and 2.25 mls writing speed using high energy laser pulses at 532 nm. It will be appreciated that laser conditions different from the standard laser conditions may be employed in one or more embodiments.

Challenges associated with laser patterning as opposed to lithographic patterning techniques include: ghostplating in the background dielectric (no longer protected by resist), identification of appropriate laser conditions, complete removal of dielectric from the patterned surface, impact of residues on nickel plating and silicide formation, clean-up etches of dielectric residues also etch background dielectric and increase ghostplating, impacts of laser melting on the selective emitter, impurity incorporation in the emitter, uniform silicide formation, and adhesion of grid metallization. Such challenges can be satisfactorily addressed by employing the steps described above.

In summary, one or more embodiments enable formation of plated grid patterns on both lithographically and laser patterned photovoltaic cells with satisfactory adhesion. Numerous processing steps were identified that can influence adhesion, the most important of which appears to be the formation of a uniform metal-rich nickel silicide layer on the emitter. Reliable silicide formation requires control of the contaminants (such as nitrogen) introduced into the emitter during selective emitter formation and use of appropriate anneal conditions, such as annealing temperatures in the range of 300-320° C. to obtain the desired metal-rich silicide phase that facilitates adhesion to subsequently-plated metals. A low stress plated nickel layer is provided in one or more embodiments to maintain intimate contact between the nickel layer and the silicon-based emitter during the silicide anneal. A low-stress plating solution such as a nickel sulfamate solution is employed in one or more embodiments. By employing a low stress plated nickel layer, delamination is minimized or avoided and continuous silicide layers, as shown in FIG. 14, can be fabricated that have uniform thickness even over texture peaks. It has further been demonstrated that this anneal could be performed in air without any detrimental effects other than some oxidation of the nickel surface which makes the use of a nickel etchant that can also etch nickel oxide, such as a ferric chloride based etchant, advisable. It was also found that a pre-plating clean step is important prior to both plating nickel on the emitter and plating the nickel flash on the silicide. It appears that it is most critical to remove any surface SiO₂ and that BOE etchants are somewhat preferable to dilute HF etchants. Laser patterning offers a dry, single step technique for removing the anti-reflective coating (ARC) from the surface of the emitter prior to electroplating a front grid pattern. Laser pitch in the busbar can also influence the adhesion; the optimal laser pitch is at or slightly above the nominal laser linewidth. A pitch range of about 0.8-1.5 the nominal laser linewidth is employed in one or more embodiments. Moreover, to produce a metal grid that minimizes series resistance in the fingers and busbars, the use a highly conductive metal is advisable. Relatively inexpensive metals promote cost efficiency provided they can be easily deposited, such as by electroplating. Copper is among the metals suitable for plated metal grids. While plated copper has relatively poor adhesion to a bare silicide surface, the use of a thin electroplated layer of another metal, such as nickel, promotes good adhesion between a silicide, such as nickel silicide, and subsequently plated copper. Selectively electroplating the front grid of a photovoltaic device is a cost-effective technique provided satisfactory adhesion is obtained. Methods are accordingly provided that ensure the adhesion of the final metallization will be sufficient for the manufacture of photovoltaic devices.

Given the discussion thus far, and with reference to the drawings and accompanying disclosure, an exemplary method for fabricating a photovoltaic device includes obtaining a substrate including a base comprising silicon, a doped emitter adjoining the base, an antireflective coating on the doped emitter, the antireflective coating being patterned such that the doped emitter has exposed surface portions, and a low-stress nickel film adjoining one or more of the exposed surface portions of the emitter. FIG. 1 shows an exemplary base 24, doped emitter 22, and antireflective coating 27, 28. The method further includes annealing the substrate (in ambient air in some embodiments) to form a metal-rich nickel silicide layer NiₓSi_{y} where x>y from the emitter and the nickel film. An exemplary patterned metal-rich nickel silicide layer 25 in the finger and busbar regions is shown schematically in FIG. 1. By annealing the substrate in air, nickel oxide is formed over the nickel silicide layer. The method would then further include the step of removing the excess nickel and nickel oxide using, for example, a ferric chloride etchant, thereby exposing a surface of the nickel silicide layer. The ferric chloride etchant is capable of removing both nickel and nickel oxide. HF can be employed if only nickel oxide removal is targeted. The method may further include the step of annealing the substrate while maintaining a temperature between 300-320° C. for at least five minutes in some embodiments to form the metal-rich nickel silicide layer. A nickel flash layer is electroplated on the surface of the metal-rich nickel silicide layer followed by electroplating a layer of copper on the nickel flash layer in some embodiments.

A further exemplary method for fabricating a photovoltaic device includes obtaining a substrate including: a base comprising silicon, a doped emitter adjoining the base, and an antireflective coating composed of either a silicon nitride layer on a silicon dioxide or aluminum oxide dielectric layer or a silicon nitride layer directly on the doped emitter, and laser patterning the antireflective coating to remove portions of the antireflective coating, thereby forming one or more trenches within the antireflective coating. The exemplary method further includes causing an increase in doping of selected regions of the emitter concurrently with the step of laser patterning the antireflective coating. The method further includes forming a low-stress nickel film on the selected regions of the doped emitter, annealing the low-stress nickel film and selected regions of the doped emitter to form metal-rich silicide regions having the composition NiₓSi_{y} where x>y from the low-stress nickel film and the selected regions of the doped emitter, forming a nickel layer on the nickel silicide regions, and electroplating a copper layer on the nickel layer. In a further embodiment of the method, the step of laser patterning includes causing a plurality of parallel laser passes of equal width, further wherein the pitch between parallel laser passes over at least one of the selected regions is between 0.8-1.5 of the width of a single laser pass. The low-stress nickel film has a thickness between 100-200 nm in one or more embodiments. The nickel layer is flash plated using nickel sulfamate in some embodiments. In embodiments wherein annealing is in ambient air, causing the formation of nickel oxide, the method further includes removing excess nickel and the nickel oxide from the metal-rich nickel silicide following annealing.

An exemplary photovoltaic structure includes a base 24 comprising silicon, a doped emitter 26 adjoining the base 24, a dielectric layer on the doped emitter, a silicon nitride antireflective coating 28 on the dielectric layer, a continuous metal-rich nickel silicide layer 25 having uniform thickness adjoining the doped emitter, and a metal grid 29A, 29B electrically connected to the metal-rich nickel silicide layer. In some embodiments, the metal grid includes plated copper fingers 29A and busbars 29B that contact a nickel layer 29C adjoining the metal-rich nickel silicide layer. The dielectric layer comprises silicon oxide in some embodiments and aluminum oxide in other embodiments. FIG. 1 shows an exemplary photovoltaic device 20 including a dielectric layer 27 comprising silicon dioxide. The top portion of FIG. 14 shows a portion of a patterned metal-rich nickel silicide layer having substantially uniform thickness that is obtained by maintaining the anneal temperature in the appropriate range. In contrast, silicide formed at a 400° C. anneal temperature has an irregular thickness, as shown in the image in the bottom portion of FIG. 14. As shown in FIG. 1, the patterned, metal-rich nickel silicide layer 25 is only in the patterned regions (fingers and busbar) of the exemplary photovoltaic device 20.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Terms such as “above” and “below” are generally employed to indicate relative positions as opposed to relative elevations unless otherwise indicated.

It will be appreciated and should be understood that the exemplary embodiments of the invention described above can be implemented in a number of different fashions. The embodiments were chosen and described in order to best explain the principles of the invention and the practical application, and to enable others of ordinary skill in the art to understand the invention for various embodiments with various modifications as are suited to the particular use contemplated. Given the teachings of the invention provided herein, one of ordinary skill in the related art will be able to contemplate other implementations of the invention.

Although illustrative embodiments of the present invention have been described herein with reference to the accompanying drawings, it is to be understood that the invention is not limited to those precise embodiments, and that various other changes and modifications may be made by one skilled in the art without departing from the scope or spirit of the invention.

What is claimed is:

1. A method for fabricating a photovoltaic device, comprising:
obtaining a substrate including:
a base comprising silicon,
a doped emitter adjoining the base, an antireflective coating on the doped emitter, the antireflective coating being patterned such that the doped emitter has exposed surface portions, and
a low-stress nickel film adjoining one or more of the exposed surface portions of the emitter, and
annealing the substrate to form a metal-rich nickel silicide layer NiₓSi_{y} where x>y from the emitter and the nickel film.

2. The method of claim 1, wherein the step of annealing the substrate is conducted in ambient air and causes the formation of nickel oxide over the metal-rich nickel silicide layer, further including removing excess nickel and the nickel oxide from the metal-rich nickel silicide layer by etching the nickel oxide using a ferric chloride etchant, thereby exposing a surface of the metal-rich nickel silicide layer.

3. The method of claim 1, further including the step of electroplating a nickel flash layer on the surface of the metal-rich nickel silicide layer.

4. The method of claim 3, further including the step of electroplating a layer of copper on the nickel flash layer.

5. The method of claim 4, wherein the step of obtaining the substrate further includes laser patterning the antireflective coating.

6. The method of claim 5, wherein the antireflective coating includes a dielectric oxide layer contacting the emitter.

7. The method of claim 5, wherein the step of obtaining the substrate further includes electroplating the low-stress nickel film on the one or more of the exposed surface portions of the emitter using a low stress plating solution.

8. The method of claim 7, wherein the low-stress nickel film has a thickness between 100-200 nm.

9. The method of claim 7, wherein the step of annealing the substrate further includes maintaining a temperature between 300-320° C.

10. The method of claim 7, further including the step of cleaning the surface of the metal-rich nickel silicide layer prior to electroplating the nickel flash layer.

11. The method of claim 5, further including the step of introducing further dopants into regions of the doped emitter while laser patterning the antireflective coating.

12. The method of claim 11, wherein the antireflective coating comprises a silicon dioxide layer on the emitter and a silicon nitride layer on the silicon dioxide layer, the doped emitter is an n-type emitter, and the base is a p-type base, further including the step of spinning a source of phosphorus on the substrate prior to laser patterning.

13. A method for fabricating a photovoltaic device, comprising:
obtaining a substrate including:
a base comprising silicon,
a doped emitter adjoining the base,
a silicon-oxide or aluminum-oxide dielectric layer on the doped emitter, and
a silicon nitride antireflective coating on the dielectric layer;
laser patterning the antireflective coating to remove portions of the antireflective coating, thereby forming one or more trenches within the antireflective coating;
causing an increase in doping of selected regions of the emitter concurrently with the step of laser patterning the antireflective coating;
forming a low-stress nickel film on the selected regions of the doped emitter;
forming metal-rich nickel silicide regions having the composition NiₓSi_{y} where x>y from the low-stress nickel film and the selected regions of the emitter by annealing the low-stress nickel film and the selected regions of the emitter;
forming a nickel layer on the nickel silicide regions following removal of the excess nickel and nickel oxide, and
electroplating a copper layer on the nickel layer.

14. The method of claim 13, wherein the step of laser patterning further includes causing a plurality of parallel laser passes of equal width, further wherein the pitch between parallel laser passes over at least one of the selected regions is between 0.8-1.5 of the width of a single laser pass.

15. The method of claim 13, wherein the step of forming the nickel layer includes plating using a nickel sulfamate bath.

16. The method of claim 13, wherein the step of forming the metal-rich nickel silicide regions further includes annealing the low-stress nickel film and the selected regions of the emitter in ambient air, thereby further forming nickel oxide, further including the step of removing excess nickel and nickel oxide from the metal-rich nickel silicide regions.

17. The method of claim 16, wherein the step of removing excess nickel and nickel oxide from the metal-rich silicide regions includes etching the metal-rich nickel silicide regions using a ferric chloride etchant.

18. The method of claim 13, wherein the low-stress nickel film has a thickness between 100-200 nm.

19. The method of claim 13 wherein the step of annealing further includes maintaining a temperature between 300-320° C.

20. A photovoltaic structure comprising:
a base comprising silicon;
a doped emitter adjoining the base;
a dielectric layer on the doped emitter;
a silicon nitride antireflective coating on the dielectric layer;
a patterned metal-rich nickel silicide layer adjoining the doped emitter, and
a metal grid electrically connected to the patterned metal-rich nickel silicide layer.
